(19) United States
(12) Patent Application Publication
(10) Pub. No.: US 2023/0332320 A1
(43) Pub. Date: Oct. 19, 2023

(54) COATINGS FOR USE IN REMOTE PLASMA SOURCE APPLICATIONS AND METHOD OF THEIR MANUFACTURE

(71) Applicant: MKS Instruments, Inc., Andover, MA (US)

(72) Inventors: Chiu-Ying TAI, Chelmsford, MA (US); Michael HARRIS, Hudson, MA (US)

(73) Assignee: MKS Instruments, Inc., Andover, MA (US)

(21) Appl. No.: 18/134,087

(22) Filed: Apr. 13, 2023

Related U.S. Application Data
(60) Provisional application No. 63/331,735, filed on Apr. 15, 2022.

(51) Int. Cl. C25D 11/02; H01J 37/32

(52) U.S. Cl. CPC C25D 11/026; H01J 37/32357; H01J 37/32862; H01J 37/32816

(57) ABSTRACT

A method of coating a plasma channel of a plasma source, comprises providing at least one electrolyte having one or more chelating agents therein, treating at least one surface to produce a processed surface, smoothing the surface of the processed surface with at least one post processing technique to produce at least one smoothed processed surface, and cleaning the smoothed surface.

### CROSS-REFERENCE TO RELATED APPLICATIONS

The present application claims the benefit of U.S. Provisional Patent Appl. No. 63/331,735, filed on Apr. 15, 2022, and entitled “Coatings for Use in Remote Plasma Source Applications and Method of Manufacture.”

### FIELD OF THE INVENTION

The present application relates to coatings used in remote plasma source applications, and a method for the manufacture of such coatings.

### BACKGROUND ART

Remote plasma sources are commonly used in the manufacture of semiconductors. Historically, remote plasma sources, remote plasma applicators and products (hereinafter RPS) have been manufactured from a variety of materials. Commonly, the plasma-facing surfaces within the RPS are modified or otherwise coated to meet the insulation requirement, extend chamber lifetime and aid in chamber cleaning between processing cycles. The selection of plasma-facing materials for aluminum-based plasma applicators in RPS products is strongly related to plasma conditions, application requirements, manufacturability, cost, and many others. Many commercially available materials and coating techniques cannot be used in remote plasma source applications due to any number of factors. For example, the geometry and complexity of the applicator design (partially enclosed inner surface, narrow plasma channel, and restrictions on overall dimensions), and the extreme operation conditions (high density of plasma, high temperature, chemical attack, and ion bombardment) greatly reduce the number of commercially available materials and coating techniques useful in RPS applications.

Hard anodized (HA) processing has been used to treat aluminum in RPS applicators for more than twenty years. The HA oxide coating offers benefits such as good chemical resistance, appropriate manufacturing process for complex geometry, and good cost effectiveness. In the past, HA coatings for RPS applications were focused on chamber clean purpose. While HA coatings have proven useful in the past, a number of shortcomings have been identified particularly with NF₃ plasmas. For example, although the anodized coating has relatively good plasma resistance in NF₃ environment, after exposing to fluorine chemistry, the amorphous aluminum oxide and hydroxide will react with fluorine to form a thin flaky layer of aluminum fluoride on top of the anodized layer which may result in contamination in RPS. Further, the anodized layer will degrade over time and reduce the operational lifetime of the block used in the RPS. In addition, the porous nature and cracks in the HA coating due to thermal mismatch in anodization also have negative impacts to its dielectric strength. Arcing problems happen especially in worn surfaces. FIGS. 1a-c illustrate these negative effects on the surface of the anodized layer. More specifically, FIG. 1a represents a porous surface of anodized surface, in plane view, while FIG. 1b represents the anodized coating with cracks and defects after plasma exposure, in a section view, and FIG. 1c represents arcing marks on curved anodized surface after plasma exposure.

In light of the foregoing, numerous alternative treatment techniques and materials have been developed. For example, plasma electrolytic oxidation (PEO) coatings have been used in some RPS applications for some time. Unlike anodization, the partially crystallized aluminum oxide in PEO coating provides more robust erosion resistance (at least 2 to 3× longer life than HA) in NF₃ plasma and other chemistries. In addition, the denser and less porous structure formed by PEO processing forms a coating having a dielectric strength approximately 1.5× to 2× higher than HA processing. Unfortunately, shortcomings of the PEO process also exist. For example, the high voltage/energy required during the film growing process breaks through the oxide layer and creates open channels to the base alloy. In addition, trace metals in base alloy may be transported over time to the surface during the process. These trace metals may oxidize and solidify after cooling down, while the PEO coating process continues until the desired thickness is reached. As a result, it has been found that some metals (such as copper, iron, and manganese) in PEO coatings have very uneven distributions due to a number of factors, including the mobility of trace metals. This high metal concentration feature in PEO surface could cause potential metal contaminations in downstream of RPS after exposing to plasma.

In some applications, hydrogen may be used to form the plasma. In application of hydrogen-related plasma (such as H2 and NH3), the PEO-coated RPS may have a significantly lower (˜40 to 50% down) output than HA-coated RPS. The lower output of the PEO-coated RPS may be caused by any number of factors, including a higher surface recombination rate of PEO coating as well as the larger surface area in PEO coating. As mentioned above, the process of PEO coating may continuously bring metals to the top surface of the coating, and then oxidize and solidify these. When the process is completed, a nodular type structure may be formed on the top surface. The nodular type structure layer thickness ranges from about 0.25 μm to 35 μm, while a thickness of overall is up to 50 um. The total surface area is approximately 3 to 4× larger than HA. As such, the larger surface area may significantly increase the chance of radical adsorption which leads to the high recombination rate. In addition, the higher metal concentrations in PEO surface and the relatively lower content of hydroxide (known to have lower H recombination rate than oxide) may also contribute to the higher recombination rate.

In light of the foregoing, there is an ongoing need for a coating for plasma-facing surfaces of an RPS which offers the benefits of both HA and PEO coatings, while avoiding their shortcomings.

### SUMMARY

The present application discloses various embodiments and methods to provide solutions to the above stated objective technical needs, as it will become evident in the following description.

In one embodiment, the present application discloses a method of coating a plasma channel of a plasma source, the method comprising providing at least one electrolyte having one or more chelating agents therein, treating at least one surface to produce a processed surface, smoothing the surface of the processed surface with at least one post processing technique to produce at least one smoothed processed surface, and cleaning the smoothed surface. The surface may be a plasma-facing surface of a plasma source, and treating the surface produces a processed surface comprising treating at least one surface using a plasma electrolytic oxidation process. Alternatively, treating the surface produces a plasma electrolytic oxidation processed surface. The post processing technique comprises a dry bead blasting process, the dry bead blasting process employing high purity aluminum oxide as blast media. The post processing technique may be performed at a pressure from about 10 psi to about 200 psi, and at a blasting angle of about 15 degrees to about 90 degrees of angle. The post processing technique is configured to remove a layer of about 0.25 nm to about 35 nm of the surface and to reduce a surface roughness and a surface area by 30 to 50% of their original size. The post processing technique comprises a vapor blasting process. The vapor blasting uses pressurized water along with at least one abrasive media to finish the surface. Cleaning comprises an application of a high frequency ultrasonic energy clean, for an extended time, to remove small sized particles and embedded process residues from said surface.

In accordance with another embodiment, the present application discloses a coating for use in remote plasma source applications.

### BRIEF DESCRIPTION OF FIGURES

The above and other aspects, features and advantages of the coatings for use in remote plasma source applications and method of their manufacture as disclosed herein will become more apparent from the subsequent description thereof, presented in conjunction with the following drawings, wherein:

FIGS. 1a-c illustrate the negative effects of hard anodized processing on the surface of an anodized layer;

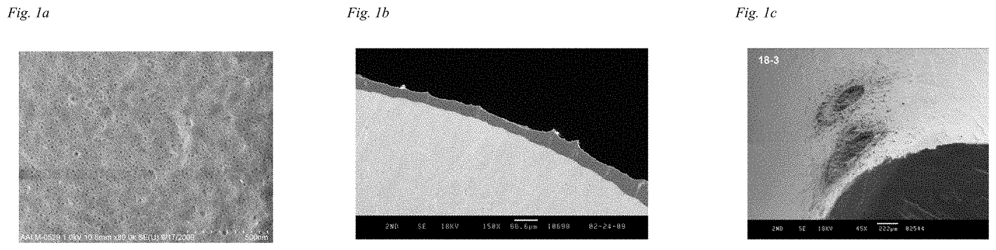

FIGS. 2a and 2b illustrate a 3D Image of a standard PEO surface, wherein the insert is in plane view, and a 3D Image of a post treated PEO surface, wherein the insert is the plane view, respectively;

FIG. 3 is an illustration of test results regarding metal levels collected in downstream wafer; and

FIG. 4 is a representation of experimental data, and

FIG. 5 shows a flow chart of a method of coating a plasma channel of a plasma source.

### DETAILED DESCRIPTION

Exemplary embodiments of a method of coating a plasma channel of a plasma source, and of a coating for use in remote plasma source applications are described below with reference to the accompanying drawings. Unless otherwise expressly stated, in the drawings the sizes, positions, etc., of components, features, elements, etc., as well as any distances therebetween, are not necessarily to scale, and may be disproportionate and/or exaggerated for clarity.

The terminology used herein is for the purpose of describing particular example embodiments only and is not intended to be limiting. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another.

Unless indicated otherwise, the term “about,” “thereabout,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those skilled in the art.

Many of the embodiments described in the following description share common components, devices, and/or elements. Like named components and elements refer to like named elements throughout. Thus, the same or similar named components or features may be described with reference to other drawings even if they are neither mentioned nor described in the corresponding drawing. Also, even elements that are not denoted by reference numbers may be described with reference to other drawings.

Many different forms and embodiments are possible without deviating from the spirit and teachings of this disclosure and so this disclosure should not be construed as limited to the example embodiments set forth herein. Rather, these example embodiments are provided so that this disclosure will be thorough and complete, and will convey the scope of the disclosure to those skilled in the art.

The present application discloses various coatings for use with remote plasma source applications, and methods of applying coatings to surfaces of a remote plasma source and devices associated therewith. In one embodiment, the coatings may be applied to plasma-facing surfaces of the remote plasma source and related devices, although those skilled in the art will appreciate that the coatings may be applied to any surface. Further, those skilled in the art will appreciate that any variety of materials may be applied using the methods described herein. For example, two potential sources of metals exist which can directly contribute to the metal concentrations in the coatings. More specifically, as described above with regard to the PEO coating, contamination may stem from the trace metals from the A16061 base alloy, and from the coating environment (e.g. corroded electrode). Therefore, among others, the present application is directed to finding solutions to prevent metal oxides to form on the surface.

Chelating agents are chemical compounds capable of binding with metal ions to form stable, water-soluble metal complexes that prevent undesirable precipitation, dissolve scale deposits and optimize oxidation processes. These materials can be used in different areas such as medical applications, corrosion control, water treatment, etc. A technique of providing a more desirable coating for plasma-facing surfaces of an RPS and related systems involves the use of one or more chelating agents to control and reduce metal levels in PEO coating. More specifically, the selected chelating agents are added to the electrolyte prior to coating. During the PEO coating process, the chelating agents couple to unwanted metal ions (either from the base alloy or the corroded electrode) in the electrolyte and near the surface region to prevent the formation of metal oxides in coating. The formed metal complexes remain in electrolyte, reducing or preventing the metals from returning to the coating.

Any variety of chelating agents or materials may be used. The selection of appropriate chelating agent material requires the consideration of different factors such as the type of ions to be removed, the strength of the formed metal complex, the pH value of the electrolyte, and their possible impact to the coating regime and quality. Further, the electrical regime may be adjusted to maintain the coating quality.

In one embodiment, post processing of the PEO-coated surfaces is performed to enhance the performance of the RPS. Any variety of a post treatment processes configured to smooth the rough surface of PEO coating may be used, such as a dry bead blasting process. For example, high purity of aluminum oxide (e.g. AlO in high purity (i.e. over 90%)) may be used as a blast media. The pressure, blasting angle, and processing time may be optimized to provide the desired surface smoothness. Exemplarily the blast media comprises particulates of 400 mesh, with ˜20 to 40 um particle size, with bulky shapes with sharp edges. Their delivery is performed by spraying with nozzles with pressurized air.

In one embodiment, post processing at a pressure and blasting angle (from about 10 psi to about 200 psi at about 15 degrees to about 90 degrees of angle) is employed, although those skilled in the art will appreciate that any variety of pressures, blasting angles, and processing times may be used to remove any amount of material from the coated surface.

In one embodiment, the pressure, blasting angle, and processing time of the post processing were optimized to remove a layer of about 0.25 μm to about 35 μm thick of the coating and to reduce the surface roughness and surface area by 30 to 50% or more from origin. The optimization was accomplished by processing many distinct samples under different angles, pressures, processing times, and media types. Subsequently, the microscope is used to measure the resulting surface area and roughness, and to elect the best conditions.

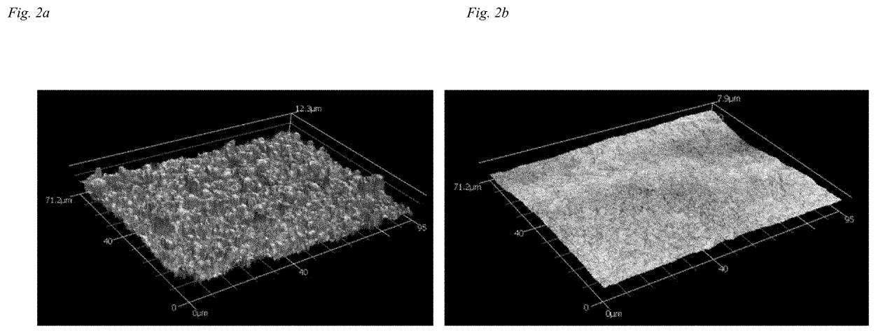

The surface created by the above-described post processing enhances the surface created by the PEO process, and surfaces with a roughness similar to that resulting from the standard PEO processed surface. Therefore, the developed bead blasting process described herein could be directly adopted and applied as well to the chelating-enhanced PEO processed surfaces to achieve the same finish on the surface. FIGS. 2a and 2b illustrate a 3D Image of a standard PEO surface, wherein the insert is in plane view, and a 3D Image of a post treated PEO surface, wherein the insert is the plane view, respectively.

Alternatively, in another embodiment, vapor blasting may be used in place of dry bead blasting. Unlike dry bead blasting, vapor blasting uses pressurized water along with at least one abrasive media to finish a surface. Further, vapor blasting is substantially a dustless process thereby providing a final surface having less embedded residues while potentially providing a surface smoother than a dry bead blasted surface.

Optionally, an optimized post cleaning process may be used to further process the coated surface after the bead blasting step. More specifically, the additional cleaning process includes the application of a higher frequency ultrasonic energy clean, for an extended time, to remove small sized particles and embedded process residues. Ultrasonic and megasonic cleaning use sound waves traveling through liquid, and produce cycles of compression and rarefaction. During rarefaction, the liquid cavitates to produce vapor-filled bubbles. The bubbles keep growing and finally implode to produce local heat and energy. The forces produced by these small implosions can physically remove the embedded particles or contaminations. Ultrasonic cleaning advantageously dissolves and displaces particles quickly and completely. The typical frequency range for ultrasonic cleaning is between 25 to 270 kHz, while a range of frequency for megasonic cleaning is in 360 kHz to 2 MHz or higher. Frequencies above 100 kHz are envisioned to be used in accordance with the present invention, in precision cleaning. In accordance with an embodiment of the present invention, frequencies of 120 kHz are used. Higher frequency cleaning (such as megasonic cleaning) is particularly useful for removal of sub-micron particles from flat surfaces. The motions of fluid in this frequency range result in more stable cavitation without implosions, which can cause less damages to the substrate. In one embodiment, the surfaces may be post processed using ultrasonic cleaning followed by dry blasting.

The processes described above offer several advantages over the prior art methods and coatings. More specifically, post-PEO process bead-blasting, and post-bead blasted ultrasonic cleaning implemented in combination with the chelating-enhanced PEO process lead to:

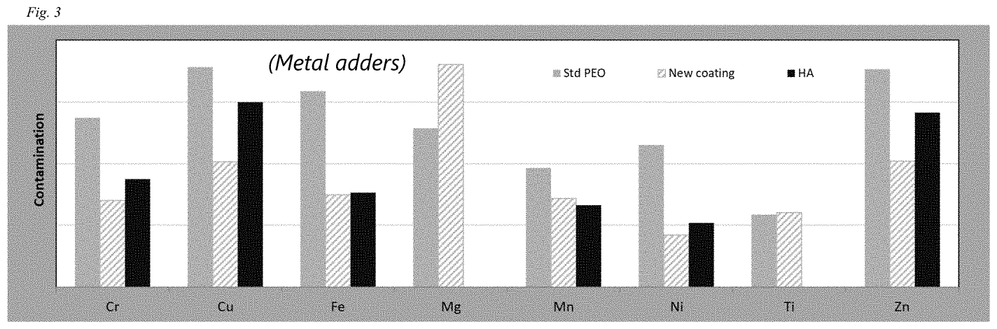

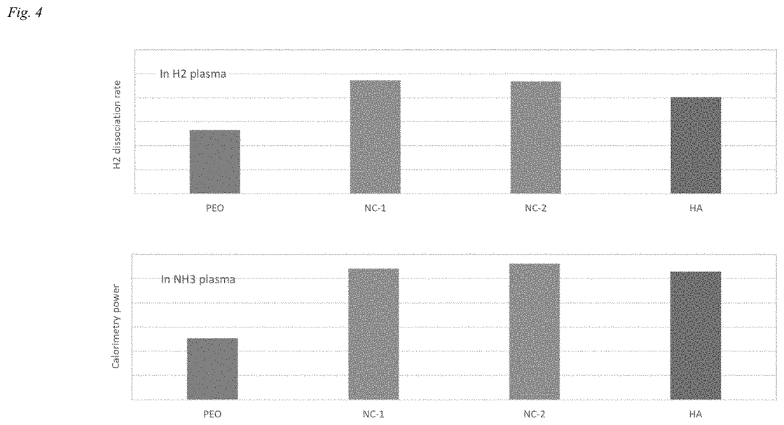

(1) Coating cleanness (low metal contaminations)—Coating inside RPS applicator is part of the plasma facing material. Some level of erosion and surface reaction are expected after exposing to plasma. The metal concentrations in coating can directly affect the metal contamination levels exit the RPS. Therefore, to reduce the metal levels in coating (the source) should make the most straightforward improvement. Test results in FIG. 3 show that most of the metal levels collected in downstream wafer have been significantly reduced. In semiconductor fabrication process, metal contamination could cause very serious damage to the wafers. Applicators with cleaner coating should increase the opportunities for RPS to be applied to on-wafer processes.
(2) Lower recombination rate/higher radical output—Previous tests have shown that standard PEO coating has much lower (— half the) radical output in hydrogen and NH3 plasmas, than HA coatings do. This may be due to the higher radical recombination rate in PEO surface. The larger surface area with nodular structure was identified as the potential root cause. The implementation of proper post treatment and cleaning processes has significantly improved the surface finish and cleanness. Experimental data (see FIG. 4, wherein PED refers to the calorimetry output of the RPS with PEO, NC-1 & 2 refer to new coatings, and HA to coating in H₂ (upper) and NH₃ (lower) plasma) confirms that coating with these treatments demonstrates equivalent (or better) output performance than PEO and HA in hydrogen-based plasma. This improvement in radical output further enhances the opportunities for RPS in applications that specifically require hydrogen-based plasma, such as etch and deposition processes.
(3) Comparatively to HA and standard PEO coatings, the coating and method described herein has the benefits of standard PEO coatings, such as high erosion resistance and dielectric strength, with additional significant improvements in reductions of metal levels and surface recombination rate. The RPS process described herein is expected to be applied with superior performance to more semi-processes beyond chamber clean.

Further, various other processing steps may be added to the methods described herein, or, in the alternative, may replace one or more of the steps described herein. For example, extrude honing may be used to finish and interior surface. More specifically, in one embodiment, a chemically inactive and non-corrosive media may be flowed through a workpiece. Abrasive particles in the media may be used to abrade unwanted material to reach a desired finish.

Optionally, atomic layer deposition (hereinafter ALD) may be used to provide a conformal coating on a surface of the RPS and be configured to provide a layer of a selected coating for a desired purpose. For example, an ALD coating of aluminum oxide, aluminum nitride or silicon oxide may offer less reactions with chlorine or hydrogen radicals.

In accordance with another embodiment, the ALD processing occurs after bead blasting the surface, although those skilled in the art will appreciate that the ALD coating may be applied at any time to the RPS.

In accordance with further alternative embodiments, instead of ALD, other deposition methods may be employed, such as CVD and PVD, taken singly or in combination.

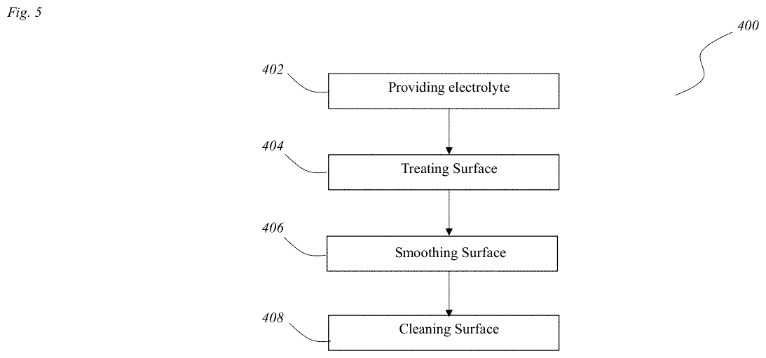

FIG. 5 illustrates in summary the method of the present invention, in accordance with one of its embodiments.

Specifically, FIG. 5 illustrates a method of coating a surface of a plasma source 400. As shown, the method 400 comprises a step of providing 402 at least one electrolyte having one or more chelating agents therein, a further step of 404 of treating at least one surface to produce a processed surface, a further yet step 406 of smoothing the surface of the processed surface with at least one post processing technique to produce at least one smoothed processed surface, and another step 408 of cleaning the smoothed surface.

The surface may be a plasma-facing surface of a plasma source, and the treating step 404 of the surface to produce a processed surface comprises treating at least one surface using a plasma electrolytic oxidation process. Treating at least one surface produces a plasma electrolytic oxidation processed surface. The post processing technique comprises a dry bead blasting process, while the dry bead blasting process employs high purity aluminum oxide as blast media.

The post processing technique may be performed at a pressure from about 10 psi to about 200 psi, and at a blasting angle of about 15 degrees to about 90 degrees of angle. In one embodiment, the post processing technique is configured to remove a layer of about 0.25 μm to about 35 μm of the surface and to reduce a surface roughness and a surface area by 30 to 50% of its original size.

Optionally, the post processing technique may comprise a vapor blasting process. The vapor blasting uses pressurized water along with at least one abrasive media to finish the surface. The cleaning step 408 comprises an application of a high frequency ultrasonic energy clean, for an extended time, to remove small sized particles and embedded process residues from the surface.

The embodiments disclosed herein are illustrative of the principles of the invention. Other modifications may be employed which are within the scope of the invention. Accordingly, the devices disclosed in the present application are not limited to that precisely as shown and described herein.

What is claimed:

1. A method of coating a plasma channel of a plasma source, comprising:
providing at least one electrolyte having one or more chelating agents therein;
treating at least one surface of said plasma channel to produce a processed surface;
smoothing a surface of the processed surface with at least one post processing technique to produce at least one smoothed processed surface; and
cleaning the smoothed surface.

2. The method of claim 1, wherein the surface is a plasma-facing surface of a plasma source.

3. The method of claim 1, wherein said treating at least one surface of said plasma channel to produce a processed surface comprising treating the at least one surface using a plasma electrolytic oxidation process.

4. The method of claim 1, wherein said treating produces a plasma electrolytic oxidation processed surface.

5. The method of claim 1, wherein said at least one post processing technique comprising a dry bead blasting process.

6. The method of claim 5, wherein said dry bead blasting process employing high purity aluminum oxide as blast media.

7. The method of claim 1, wherein said at least one post processing technique performed at a pressure from about 10 psi to about 200 psi, and at a blasting angle of about 15 degrees to about 90 degrees.

8. The method of claim 1, wherein said at least one post processing technique is configured to remove a layer of about 0.25 μm to about 35 μm of said surface and to reduce a surface roughness and a surface area by 30 to 50% of its original size.

9. The method of claim 1, wherein said at least one post processing technique comprising a vapor blasting process.

10. The method of claim 1, wherein said vapor blasting using pressurized water along with at least one abrasive media to finish said surface.

11. The method of claim 1, wherein said cleaning comprises an application of a high frequency ultrasonic energy clean, for an extended time, to remove small sized particles and embedded process residues from said surface.

12. A coating for use in a remote plasma source application, comprising:
a surface, said surface obtained by providing at least one electrolyte having one or more chelating agents therein;
treating at least one surface to produce a processed surface;
smoothing the surface of the processed surface with at least one post processing technique to produce at least one smoothed processed surface; and
cleaning the smoothed surface.

13. The coating of claim 12, wherein the surface comprising a plasma-facing surface of a plasma source.

14. The coating of claim 12, wherein said surface comprising a plasma electrolytic oxidation processed surface.
